(19) United States
(12) Patent Application Publication
(10) Pub. No.: US 2017/0317235 A1
(43) Pub. Date: Nov. 2, 2017

(54) NITRIDE SEMICONDUCTOR LIGHT-EMITTING ELEMENT

(71) Applicant: Sharp Kabushiki Kaisha, Sakai City, Osaka (JP)

(72) Inventors: Katsuji IGUCHI, Sakai City (JP); Yoshihiko TANI, Sakai City (JP); Kentaro NONAKA, Sakai City (JP)

(21) Appl. No.: 15/520,852

(22) PCT Filed: Sep. 9, 2015
(86) PCT No.: PCT/JP2015/075558

§ 371 Date: Apr. 21, 2017

(30) Foreign Application Priority Data
Nov. 6, 2014 (JP) 2014-226094

(51) Int. Cl. H01L 33/24; H01L 33/06; H01L 33/32; H01L 33/02; H01L 33/16

(52) U.S. Cl. CPC H01L 33/24; H01L 33/32; H01L 33/025; H01L 33/06; H01L 33/16

(57) ABSTRACT

A nitride semiconductor light-emitting element at least includes an underlayer, an n-type contact layer, a light-emitting layer, and a p-type nitride semiconductor layer successively disposed on a substrate. The film thickness ratio R, the ratio of the thickness of the n-type contact layer to the thickness of the underlayer, is 0.8 or less. The number density of V-pits in the surface of the light-emitting layer located on the p-type nitride semiconductor layer side is 1.5×10⁸/cm² or less. This can provide a nitride semiconductor light-emitting element that can realize improvements in the light emission efficiency at the actual operating temperature and the temperature characteristic and an improvement in the ESD resistance without causing conflict.

### TECHNICAL FIELD

The present invention relates to a nitride semiconductor light-emitting element.

### BACKGROUND ART

Nitrogen-containing III-V group compound semiconductors (hereinafter referred to as “group III nitride semiconductors”) have band gap energies corresponding to light energies having wavelengths in the infrared to ultraviolet region. The group III nitride semiconductors are accordingly useful as materials for light-emitting elements emitting light having wavelengths in the infrared to ultraviolet region or as materials for light-receiving elements receiving light having wavelengths in the infrared to ultraviolet region.

In group III nitride semiconductors, the bonding forces between the atoms constituting a group III nitride semiconductor are large, the dielectric breakdown voltage is high, and the saturation electron velocity is high. Based on these characteristics, the group III nitride semiconductors are also useful as materials for electronic devices such as high frequency transistors exhibiting high temperature resistance and high output. In addition, the group III nitride semiconductors hardly damage the environment and are therefore gathering attention as materials easy to handle.

A nitride semiconductor light-emitting element including such a group III nitride semiconductor generally employs a quantum well structure as the light-emitting layer. Application of a voltage to the nitride semiconductor light-emitting element recombines electrons and holes in the well layer constituting the light-emitting layer to generate light. The light-emitting layer may have a single quantum well (SQW) structure or may have a multiple quantum well (MQW) structure composed of alternately stacked well layers and barrier layers.

In nitride semiconductor light-emitting elements emitting visible light, in general, the well layer of the light-emitting layer is an InGaN layer, and the barrier layer of the light-emitting layer is a GaN layer. This allows production of, for example, a blue light-emitting diode (LED) having an emission peak wavelength of about 450 nm and also allows production of a white LED by combining this blue LED with a fluorescent material. The use of an AlGaN layer as the barrier layer is assumed to increase the difference between the band gap energies of the barrier layer and the well layer and thereby to enhance the light emission efficiency, but has another problem of difficulty in obtaining high-quality crystals of AlGaN, compared with GaN. In nitride semiconductor light-emitting elements emitting near-ultraviolet or ultraviolet light, an AlGaN layer is generally used as the barrier layer.

A light-emitting layer is disposed between an n-type nitride semiconductor layer and a p-type nitride semiconductor layer. The n-type nitride semiconductor layer includes an n-type contact layer, which is connected to an n-side electrode connected to an external connection terminal. In order to make a nitride semiconductor light-emitting element uniformly emit light and to reduce the operating voltage of the nitride semiconductor light-emitting element, it is necessary to reduce the sheet resistance of the n-type contact layer, to increase the concentration of the n-type impurity in the n-type contact layer (for example, to 1×10¹⁹/cm³), and to form the n-type contact layer with a large thickness (1 to 4 μm). In nitride semiconductor light-emitting elements emitting light in the visible to ultraviolet region, the n-type contact layers are GaN layers in many cases. In nitride semiconductor light-emitting elements emitting light in the ultraviolet region, the n-type contact layers are AlGaN layers in many cases.

The n-type contact layer is disposed on an underlayer. The underlayer is disposed on a buffer layer disposed on a sapphire substrate. The upper surface of the sapphire substrate is provided with regularly formed convexes for improving the light-extraction efficiency of the nitride semiconductor light-emitting element. A GaN layer or AIN layer having a thickness of about 20 nm is employed as the buffer layer, and an undoped GaN layer having a thickness of about 1 to 4 μm is used as the underlayer in many cases.

With the aim of enhancing the internal quantum efficiency of the light-emitting layer, a distorted superlattice layer or an n-type buffer layer having any of various structures, such as a layered structure of undoped and Si-doped layers, disposed between the n-type contact layer and the light-emitting layer is employed.

In addition, a variety of attempts have been tried to improve the internal quantum efficiency of a light-emitting layer. The attempts are roughly classified into two types of approaches. In a first approach, at least a certain quantity (2.0×10⁸/cm²) of dislocations starting from an intermediate layer disposed between a substrate and an n-type nitride semiconductor layer are formed to form V-pits in the light-emitting layer and thereby to aim to improve the light emission efficiency (e.g., PTL 1 (International Publication No. WO2010/150809)). In a second approach, the dislocation density is reduced as much as possible and thereby to aim to improve the light emission efficiency (e.g., PTL 2 (International Publication No. WO2013/187171)). The first approach and the second approach are assumed to differ in the mechanism of injecting holes into a light-emitting layer.

Up to now, the n-type buffer layer has been more important than the n-type contact layer as a factor for determining the characteristics of a nitride semiconductor light-emitting element. However, the effects by optimization of the structure located lower than the n-type buffer layer, such as the underlayer and the n-type contact layer, have become more important with the progress in optimization of the n-type buffer layer.

In general, an increase in the thickness of the underlayer is assumed to improve the crystallinity of, for example, the light-emitting layer. However, the crystallinity of, for example, the light-emitting layer is not necessarily determined only by the thickness of the underlayer. In addition, in the first approach, an increase in the thickness of the underlayer does not necessarily contribute to the improvement in light output. In contrast, in the second approach, it is inferred that an increase in the thickness of the underlayer has a high possibility of contributing to the improvement in light output. However, there is no disclosure for the thickness of the underlayer or the n-type contact layer optimized from the viewpoint of improving the internal quantum efficiency of the light-emitting layer.

In the example of PTL 3 (Japanese Unexamined Patent Application Publication No. 2000-232236), it is described that an n-type contact layer (thickness: 3 μm) of GaN doped with 3×10¹⁹/cm³ of Si and an undoped GaN layer (thickness: 100 Å) are successively grown on an undoped GaN layer (thickness: 1 μm).

In the example of PTL 4 (Japanese Unexamined Patent Application Publication No. 2012-248656), it is described that a pit burying layer (thickness: about 2.0 μm) of undoped GaN and an n-type contact layer (thickness: about 4.2 μm) of GaN doped with 9×10¹⁸/cm³ of Si are grown on a low-dislocation layer (thickness: about 1.5 μm) of undoped GaN.

In the example of PTL 5 (International Publication No. WO2011/004890), it is described that an n-type contact layer of Si-doped n-type GaN having a thickness of 3.2 μm is grown on an underlayer of undoped GaN having a thickness of 5 μm.

In the example of PTL 6 (Japanese Unexamined Patent Application Publication No. 2010-135490), it is described that a Si-doped n-type GaN contact layer having a thickness of 2 μm is grown on an underlayer of undoped GaN having a thickness of 8 μm.

In PTL 7 (International Publication No. WO2011/162332), the thickness of the underlayer and the thickness of the n-type contact layer have been variously investigated from the viewpoint of reducing the light emission wavelength distribution σ of the light-emitting layer. In the example, a GaN layer having a thickness of 9.6 μm and a GaN layer having a thickness of 8.6 μm are suggested as the underlayer, and a Si-doped n-type GaN layer having a thickness of 2 to 4 μm is suggested as the n-type contact layer.

These literatures disclose a variety of configurations of the underlayer and the n-type contact layer, but do not describe any specific relationship between each structure of the underlayer and n-type contact layer and the light emission efficiency.

### CITATION LIST

### Patent Literature

PTL 1: International Publication No. WO 2010/150809

PTL 2: International Publication No. WO2013/187171

PTL 3: Japanese Unexamined Patent Application Publication No. 2000-232236

PTL 4: Japanese Unexamined Patent Application Publication No. 2012-248656

PTL 5: International Publication No. WO2011/004890

PTL 6: Japanese Unexamined Patent Application Publication No. 2010-135490

PTL 7: International Publication No. WO2011/162332

### SUMMARY OF INVENTION

### Technical Problem

In order to further improve the light emission efficiency, it is necessary to improve the light emission efficiency at the actual operating temperature of the nitride semiconductor light-emitting element and to improve the temperature characteristic of the nitride semiconductor light-emitting element, (where the phrase “temperature characteristic of a nitride semiconductor light-emitting element” refers to the ratio of the light emission efficiency at a high temperature (for example, 80° C.) to the light emission efficiency at a room temperature; in general, the temperature characteristic of a nitride semiconductor light-emitting element decreases with an increase of the operating temperature of the nitride semiconductor light-emitting element; and a high temperature characteristic is required from a practical viewpoint). In order to improve the light emission efficiency and the temperature characteristic, a reduction in the number of dislocations (penetration dislocations) penetrating the light-emitting layer is indispensable. In order to reduce the dislocation density, an enhancement in the crystallinity of the light-emitting layer is necessary. In order to enhance the crystallinity of the light-emitting layer, an improvement in the crystallinity of the n-type contact layer and an improvement in the crystallinity of the underlayer are necessary.

Another issue is an improvement in electrostatic discharge (ESD) resistance. In blue light-emitting elements, not only an improvement in performance but also a reduction in initial failure are highly required in the market. Accordingly, it is indispensable to carry out ESD failure screening (detection of the quality of ESD resistance by screening) before shipping nitride semiconductor light-emitting elements. The ESD failure screening before shipping, however, causes a reduction in shipping yield of nitride semiconductor light-emitting elements and also causes an increase in cost of nitride semiconductor light-emitting elements. Consequently, an improvement in the electrical resistance of an epi-layer (epitaxially grown layer) is an urgent matter.

Nitride semiconductor light-emitting elements are thus required to enhance the crystallinity of the light-emitting layer and to enhance the ESD resistance. However, an increase in the thickness of the underlayer or the n-type contact layer for increasing the crystallinity of the light-emitting layer causes another problem, an increase in the defective rate of ESD resistance. Therefore, nitride semiconductor light-emitting elements are required to realize improvements in the light emission efficiency at the actual operating temperature and the temperature characteristic and an improvement in the ESD resistance, without causing conflict. It is an object of the present invention to provide a nitride semiconductor light-emitting element that can realize improvements in the light emission efficiency at the actual operating temperature and the temperature characteristic and an improvement in the ESD resistance without causing conflict.

### Solution to Problem

The nitride semiconductor light-emitting element of the present invention at least includes an underlayer, an n-type contact layer, a light-emitting layer, and a p-type nitride semiconductor layer successively disposed on a substrate. The film thickness ratio R, the ratio of the thickness of the n-type contact layer to the thickness of the underlayer, is 0.8 or less. The number density of V-pits in the surface of the light-emitting layer located on the p-type nitride semiconductor layer side is 1.5×10⁸/cm² or less. Preferably, the film thickness ratio R is 0.6 or less.

The concentration of conductive impurity in the underlayer is preferably 1.0×10¹⁷/cm³ or less. More preferably, the underlayer is intentionally undoped with any conductive impurity.

The underlayer is preferably made of a nitride semiconductor represented by the formula: Alₓ₁In_{y1}Ga_{1-x1-y1}N (0≦x1<1, 0≦y1≦1). The n-type contact layer is preferably made of a nitride semiconductor represented by the formula: Alₓ₂In_{y2}Ga_{1-x2-y2}N (0≦x2<1, 0≦y2≦1). More preferably, the underlayer and the n-type contact layer differ in the concentration of the conductive impurity, but have the same composition. Further preferably, both the underlayer and the n-type contact layer are made of GaN or made of AlGaN. The underlayer preferably has a thickness of 4.5 μm or more.

### Advantageous Effects of Invention

The nitride semiconductor light-emitting element of the present invention can realize improvements in the light emission efficiency at the actual operating temperature and the temperature characteristic and an improvement in the ESD resistance without causing conflict.

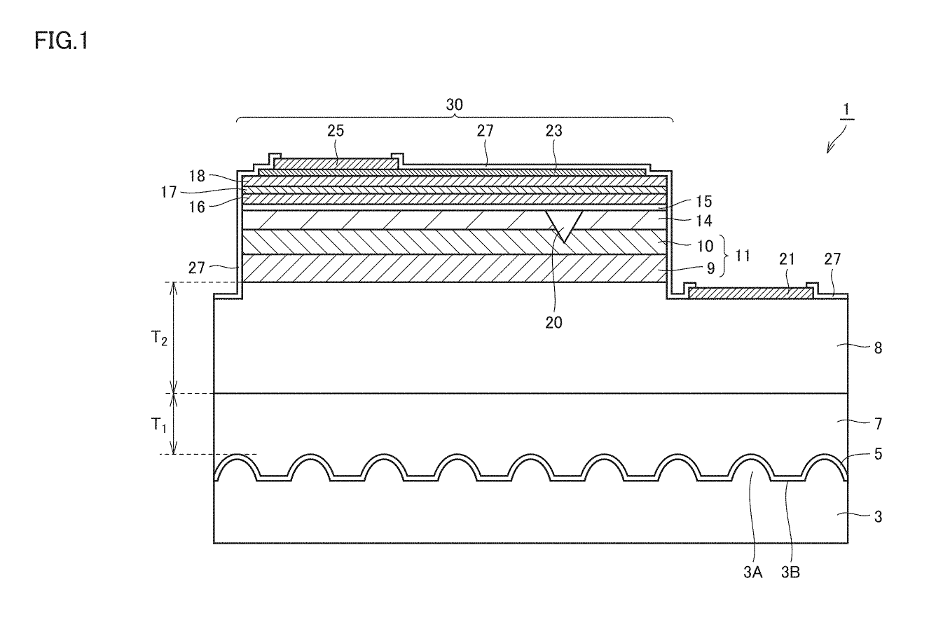

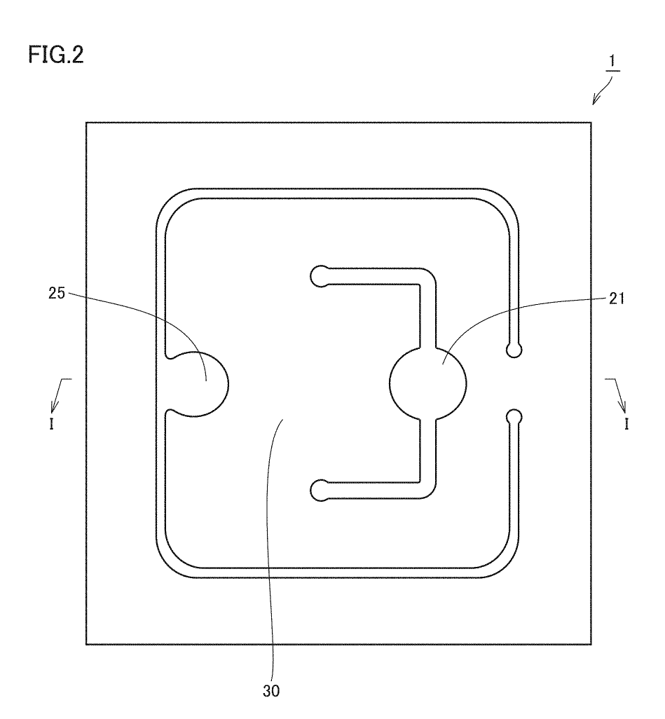

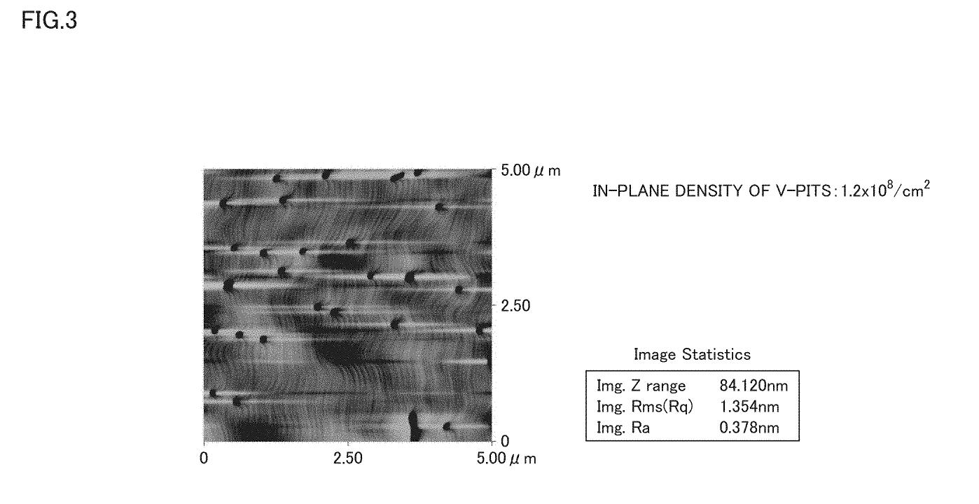

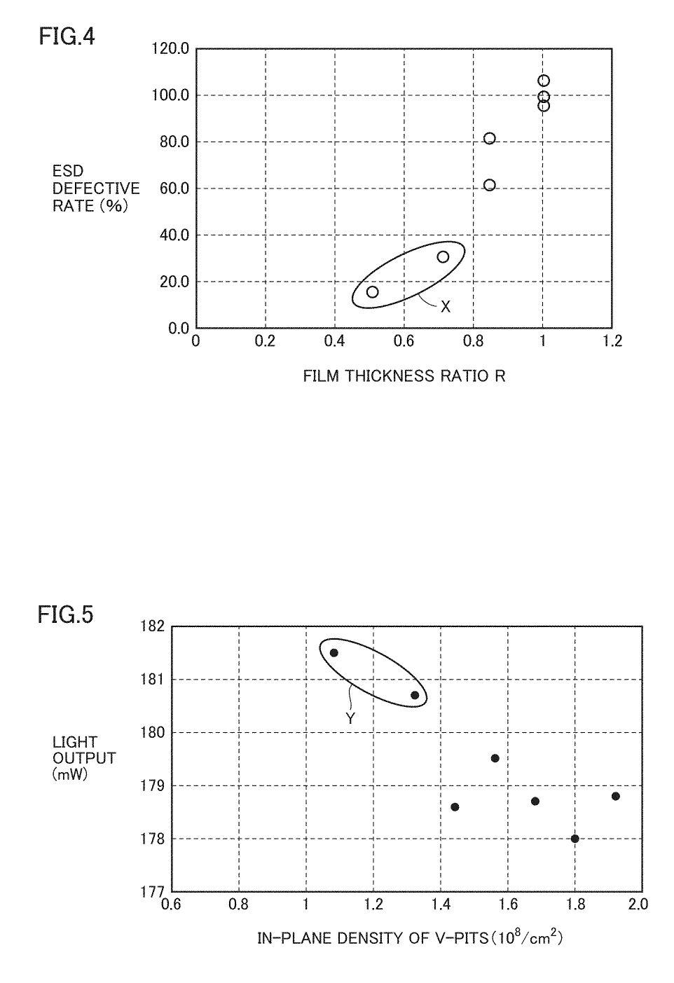

### BRIEF DESCRIPTION OF DRAWINGS

[FIG. 1] FIG. 1 is a cross-sectional view of a nitride semiconductor light-emitting element of an embodiment of the present invention.

[FIG. 2] FIG. 2 is a planar view of a nitride semiconductor light-emitting element of an embodiment of the present invention.

[FIG. 3] FIG. 3 is an image showing the results of observation by atomic force microscopy (AFM) of the upper surface of the light-emitting layer of a nitride semiconductor light-emitting element of an embodiment of the present invention.

[FIG. 4] FIG. 4 is a graph showing the relationship (experimental results) between the film thickness ratio R and the defective rate of ESD resistance (ESD defective rate).

[FIG. 5] FIG. 5 is a graph showing the relationship (experimental results) between the in-plane density of V-pits and the light output of the nitride semiconductor light-emitting element.

### DESCRIPTION OF EMBODIMENTS

A nitride semiconductor light-emitting element of the present invention will now be described using the drawings. In the drawings of the present invention, the same reference numerals indicate the same or corresponding parts. The dimensional relationships, such as length, width, thickness, and depth, are appropriately modified for clarification and simplification of the drawings and do not indicate the actual dimensional relationships.

Hereinafter, in order to show the positional relationship, the part shown in the lower side of FIG. 1 may be referred to as “bottom”, and the part shown in the upper side of FIG. 1 may be referred to “top”. This is expression for convenience and differs from the “top” and “bottom” determined with respect to the gravity direction.

Hereinafter, the term “concentration of a conductive impurity” and the term “carrier concentration”, which is the concentration of electrons occurred due to doping with an n-type impurity or the concentration of holes occurred due to doping with a p-type impurity, are used.

The term “carrier gas” refers to a gas other than group III raw-material gases, group V raw-material gases, and impurity raw-material gases (raw materials of conductive impurities). The atoms constituting the carrier gas are not incorporated into a layer, such as a nitride semiconductor layer.

The “n-type nitride semiconductor layer” may contain an n-type layer having a low carrier concentration or an undoped layer having a thickness that does not practically disturb the flow of electrons. The “p-type nitride semiconductor layer” may contain a p-type layer having a low carrier concentration or an undoped layer having a thickness that does not practically disturb the flow of holes. The term “not practically disturb” refers to a practical level of the operating voltage of a nitride semiconductor light-emitting element.

### [Configuration of Nitride Semiconductor Light-Emitting Element]

FIG. 1 is a cross-sectional view of a nitride semiconductor light-emitting element according to an embodiment of the present invention and is a cross-sectional view taken along line I-I of FIG. 2. FIG. 2 is a planar view of the nitride semiconductor light-emitting element 1.

The nitride semiconductor light-emitting element 1 includes a substrate 3, a buffer layer 5, an underlayer 7, an n-type contact layer 8, an n-type buffer layer 11, a light-emitting layer 14, an intermediate layer 15, and p-type nitride semiconductor layers 16, 17, and 18. The n-type buffer layer 11 is generally constituted of a plurality of layers, for example, a low-temperature n-type nitride semiconductor layer (functioning as a V-pit generating layer) 9 and a multilayer structure 10 (multilayer structure 10 has, for example, a superlattice structure).

A part of the n-type contact layer 8, the n-type buffer layer 11, the light-emitting layer 14, the intermediate layer 15, and the p-type nitride semiconductor layers 16, 17, and 18 are etched to form a mesa portion 30. A transparent electrode 23 is disposed on the upper surface of the p-type nitride semiconductor layer 18, and a p-side electrode 25 is disposed thereon. An n-side electrode 21 is disposed on the exposed surface of the n-type contact layer 8 surrounding the mesa portion 30 (the right side in FIG. 1). A transparent protective film 27 covers the transparent electrode 23 and the side surface of each layer exposed by etching. The n-side electrode 21 and the p-side electrode 25 are exposed from the transparent protective film 27.

Partial occurrence of V-pits 20 was verified by observation of a cross section of the nitride semiconductor light-emitting element 1 with a scanning transmission electron microscope (scanning transmission electron microscopy) at an ultra-high magnification.

The configuration of the nitride semiconductor light-emitting element 1 and a method of producing thereof are as those described in detail in PTL 2, and conventionally known techniques described in, for example, PTL 2 can be used without any limitation unless referred to otherwise below. In particular, in the present invention, the structure located higher than the n-type contact layer 8 in the nitride semiconductor light-emitting element 1 is not particularly limited. Regarding the materials, compositions, formation processes, formation conditions, thicknesses, concentrations of conductive impurities, and so on of the configurations, for example, conventionally known techniques can be appropriately combined.

For example, the p-type nitride semiconductor layer is generally constituted of a p-type AlGaN layer 16, a p-type GaN layer 17, and a p-type contact layer 18 stacked from the substrate 3 side. However, in the present invention, the p-type nitride semiconductor layer may have any configuration. The detailed explanation of the configuration of the p-type nitride semiconductor layer is omitted hereinafter.

The planar structure of the nitride semiconductor light-emitting element 1 shown in FIG. 2 is also not particularly limited in the present invention, and a variety of planar structures can be employed. For example, a structure capable of realizing a flip chip connection, i.e., an inversion connection of the nitride semiconductor light-emitting element 1 to a substrate, can also be employed. Thus, in the present invention, the nitride semiconductor light-emitting element 1 may have any planar structure. The detailed explanation of the planar structure of the nitride semiconductor light-emitting element 1 is omitted hereinafter.

### <Substrate>

The substrate 3 may be an insulating substrate, such as a sapphire substrate, or may be a conductive substrate, such as a GaN substrate, a SiC substrate, or a ZnO substrate. The thickness of the substrate 3 in the growth period of the nitride semiconductor layer varies depending on the size of the substrate 3 and is not necessarily restricted, but a substrate having a diameter of 150 mm preferably has a thickness of, for example, 900 μm or more and 1200 μm or less. The substrate 3 of the nitride semiconductor light-emitting element 1 preferably has a thickness of, for example, 50 μm or more and 300 μm or less.

The upper surface (the surface on which the buffer layer 5 is formed) of the substrate 3 preferably has an uneven shape composed of convexes 3A and concaves 3B as shown in FIG. 1. The shape of the convexes 3A on the upper surface of the substrate 3 is preferably approximately circular or polygonal (see FIG. 1). The convexes 3A are preferably disposed at positions corresponding to the vertices of approximate triangles in a planar view, and the intervals between adjacent vertices are each preferably 1 μm or more and 5 μm or less. Although the convexes 3A may be each formed into a trapezoidal shape in a side view, the vertex of the convex 3A in a side view is preferably formed into a semicircular or triangular shape.

The substrate 3 may be removed after growth of the nitride semiconductor layer. That is, the nitride semiconductor light-emitting element 1 may not have the substrate 3.

### <Buffer Layer>

The buffer layer 5 is preferably, for example, an Alₛ₀Gaₜ₀Oᵤ₀N₁₋ᵤ₀ (0≦s0≦1, 0≦t0≦1, 0≦u0≦1, s0+t0≠0) layer and more preferably an AlN layer or AlON layer. The thickness of the buffer layer 5 is not particularly limited and is preferably 3 nm or more and 100 nm or less, more preferably 5 nm or more and 50 nm or less.

### <Underlayer>

The underlayer 7 is formed on the upper surface of the buffer layer 5 by, for example, a metal organic chemical vapor deposition (MOCVD) method. The underlayer 7 is preferably made of a nitride semiconductor represented by, for example, the formula: Alₓ₁In_{y1}Gal_{1-x1-y1}N (0≦x1<1, 0≦y1≦1). The underlayer 7 is preferably made of a nitride semiconductor containing Ga as the group III element in order not to inherit the crystal defects, such as dislocations, in the buffer layer 5.

The underlayer 7 may be doped with an n-type impurity in a range of 1×10¹⁷/cm³ or less. This decreases the dislocation density to improve the crystallinity. However, the underlayer 7 is preferably intentionally undoped with any conductive impurity (for example, an n-type impurity or a p-type impurity) from the viewpoint of maintaining good crystallinity of the light-emitting layer 14. In other words, the underlayer 7 is preferably an undoped layer. The phrase “underlayer 7 is intentionally undoped with any conductive impurity” means that the underlayer 7 is grown without flowing any impurity raw-material gas in the growth process. In the underlayer 7 grown with a normal MOCVD apparatus without flowing any impurity raw-material gas, the concentration of a conductive impurity in the underlayer 7 is generally equal to or less than the detection limit of an analyzer for analyzing the concentration of a conductive impurity. For example, in the case of measuring the concentration of silicon by secondary ion mass spectrometry (SIMS), the detection limit concentration of silicon by SIMS is 7×10¹⁶/cm³.

The conductive impurity for doping the underlayer 7 can be an n-type impurity, for example, at least one of Si, Ge, and Sn, and is preferably Si. In the case of using Si as the conductive impurity, the n-type impurity raw-material gas is preferably silane or disilane.

The defects in the underlayer 7 can be reduced by increasing the thickness of the underlayer 7 as much as possible. An increase in the thickness of the underlayer 7, however, causes problems, such as occurrence of poor ESD resistance or a reduction in the productivity of the nitride semiconductor light-emitting element 1. This point will be described later.

### <N-Type Contact Layer>

The n-type contact layer 8 is preferably a layer made of a nitride semiconductor represented by the formula: Alₓ₂In_{y2}Ga_{1-x2-y2}N (0≦x2≦1, 0≦y2≦1) and doped with an n-type impurity and more preferably a layer made of a nitride semiconductor represented by the formula: Alₓ₂Ga₁₋ₓ₂N (0≦x2<1, preferably 0≦x2≦0.5, and more preferably 0≦x2≦0.1) and doped with an n-type impurity.

The n-type impurity for doping the n-type contact layer 8 is preferably, for example, Si, P, As, or Sb and more preferably Si. This can also be applied to the n-type nitride semiconductor layer (for example, n-type buffer layer 11) described layer. The concentration of the n-type impurity is not particularly limited and is preferably 1.2×10¹⁹/cm³ or less.

The resistance of the n-type contact layer 8 can be reduced by increasing the thickness of the n-type contact layer 8 as much as possible. An increase in the thickness of the n-type contact layer 8, however, causes problems, such as occurrence of poor ESD resistance or a reduction in productivity of the nitride semiconductor light-emitting element 1. This point will be described later.

### <Low-Temperature N-Type Nitride Semiconductor Layer (V-Pit Generating Layer)>

Since the lower structure until the n-type contact layer 8 in the nitride semiconductor light-emitting element 1 has a very large thickness, it is necessary to grow the lower structure until the n-type contact layer 8 within a time as short as possible while guaranteeing a certain level of crystallinity. Accordingly, the temperature of forming the lower structure until the n-type contact layer 8 is generally several hundreds of degrees Celsius higher than the temperature forming the light-emitting layer 14. The n-type buffer layer 11 has a role as a buffer layer for conversion from the growth of the lower structure until the n-type contact layer 8 to the growth of the light-emitting layer 14. The growth temperature of the n-type buffer layer 11 is lower than the growth temperature of the n-type contact layer 8 and higher than the growth temperature of the light-emitting layer 14. The layer of the n-type buffer layer 11 in contact with the n-type contact layer 8 is the low-temperature n-type nitride semiconductor layer 9. The growth temperature of the n-type contact layer 8 is decreased to grow a low-temperature n-type nitride semiconductor layer 9, which allows starting of occurrence of V-pits 20 in the low-temperature n-type nitride semiconductor layer 9. Accordingly, the low-temperature n-type nitride semiconductor layer 9 functions as a V-pit 20 generating layer. The term “low temperature” of the low-temperature n-type nitride semiconductor layer 9 means that the growth temperature is lower than the growth temperature of the n-type contact layer 8.

The low-temperature n-type nitride semiconductor layer (V-pit generating layer) 9 is preferably, for example, a highly doped n-type GaN layer having a thickness of 25 nm. The term “highly doped” herein means that the concentration of the n-type impurity is 3×10¹⁸/cm³ or more. A too high concentration of the n-type impurity in the low-temperature n-type nitride semiconductor layer (V-pit generating layer) 9 may cause a reduction in the light emission efficiency of the light-emitting layer 14 formed on the low-temperature n-type nitride semiconductor layer (V-pit generating layer) 9. Accordingly, the concentration of the n-type impurity in the low-temperature n-type nitride semiconductor layer (V-pit generating layer) 9 is preferably 1.2×10¹⁹/cm³ or less.

The low-temperature n-type nitride semiconductor layer (V-pit generating layer) 9 is preferably a layer of Alₛ₃Gaₜ₃Inᵤ₃N (0≦s3≦1, 0≦t3≦1, 0≦u3≦1, s3+t3+u3=1) doped with an n-type impurity and more preferably a layer of Inᵤ₃Gal₁₋ᵤ₃N (0≦u3≦1, preferably 0≦u3≦0.5, more preferably 0≦u3≦0.15) doped with an n-type impurity.

Such a low-temperature n-type nitride semiconductor layer (V-pit generating layer) 9 preferably has a thickness of 5 nm or more and more preferably 10 nm or more.

### <Multilayer Structure>

A multilayer structure 10 is preferably disposed between the low-temperature n-type nitride semiconductor layer (V-pit generating layer) 9 and the light-emitting layer 14. The main function of the multilayer structure 10 is the isolation between the low-temperature n-type nitride semiconductor layer (V-pit generating layer) 9 and the light-emitting layer 14 to flatten and smoothen, as much as possible, the surface of the growth structure at the time of starting the growth of the light-emitting layer 14 and further to enlarge the V-pit 20 to at least a certain size.

The multilayer structure 10 is preferably a superlattice layer having a superlattice structure. The term “superlattice layer” refers to a layer composed of alternately stacked crystal layers having different compositions from each other (each crystal layer has a very small thickness, such as 10 nm or less) and thereby having a periodic structure of a crystal lattice longer than the basic unit lattice. In general, in the multilayer structure 10, wide band gap layers and narrow band gap layers having band gap energies smaller than those of the wide band gap layers are alternately stacked to constitute a superlattice structure. The multilayer structure 10 does not necessarily have a superlattice structure and may be constituted by stacking layers having thicknesses larger than those of the above-mentioned crystal layers.

Each of the wide band gap layers is preferably, for example, an Alₐ₁Ga_{b1}In_{1-a1-b1}N (0≦a1≦1, 0<b1≦1) layer, more preferably a GaN layer. Each of the narrow band gap layers preferably has a band gap energy smaller than that of the wide band gap layer and larger than that of the well layer (described later). The narrow band gap layer is preferably an Alₐ₂Ga_{b2}In_{1-a2-b2}N (0≦a2<1, 0<b2<1, (1−a1−b1)<(1−a2−b2)) layer and more preferably a Ga_{b2}In_{1-b2}N (0<b2<1) layer.

At least one of the wide band gap layers and the narrow band gap layers preferably contains an n-type impurity. This can reduce the driving voltage of the nitride semiconductor light-emitting element 1. When at least one of the wide band gap layers and the narrow band gap layers contains an n-type impurity, the concentration of the n-type impurity is preferably 1.2×10¹⁹/cm³ or less. The n-type impurity is not particularly limited and is preferably, for example, Si, P, As, or Sb and more preferably Si.

When a combination of one wide band gap layer and one narrow band gap layer is defined as one set, the multilayer structure 10 preferably includes several to about twenty sets of the wide band gap layer and the narrow band gap layer. This can further isolate the low-temperature n-type nitride semiconductor layer (V-pit generating layer) 9 from the light-emitting layer 14.

If the multilayer structure 10 includes 20 or more sets of the wide band gap layer and the narrow band gap layer, the five sets of the wide band gap layer and the narrow band gap layer located on the light-emitting layer 14 side preferably contain an n-type impurity. This can increase the number of electrons to be injected into the light-emitting layer 14. Accordingly, the light output of the nitride semiconductor light-emitting element 1 is improved. In addition, the driving voltage of the nitride semiconductor light-emitting element 1 can be reduced.

If the multilayer structure 10 has a superlattice structure of an undoped layer and a superlattice structure of an n-type semiconductor layer, the multilayer structure 10 can have the following configuration: A superlattice structure composed of 17 sets of a wide band gap layer (undoped layer) and a narrow band gap layer (undoped layer) is disposed on the low-temperature n-type nitride semiconductor layer (V-pit generating layer) 9; and on the superlattice structure, a superlattice structure composed of three sets of a wide band gap layer (n-type semiconductor layer) and a narrow band gap layer (n-type semiconductor layer) is disposed.

If the multilayer structure 10 includes a superlattice structure composed of undoped layers and a superlattice structure composed of n-type semiconductor layers, the multilayer structure 10 may have the following configuration: A first superlattice structure composed of five sets of a wide band gap layer (n-type semiconductor layer) and a narrow band gap layer (n-type semiconductor layer) is disposed on the low-temperature n-type nitride semiconductor layer (V-pit generating layer) 9; a second superlattice structure composed of ten sets of a wide band gap layer (undoped layer) and a narrow band gap layer (undoped layer) is disposed on the first superlattice structure; and a third superlattice structure composed of five sets of a wide band gap layer (n-type semiconductor layer) and a narrow band gap layer (n-type semiconductor layer) is disposed on the second superlattice structure.

The thickness of the multilayer structure 10 is preferably 40 nm or more, more preferably 50 nm or more, and further preferably 60 nm or more, and is preferably 100 nm or less and more preferably 80 nm or less. A thickness of the multilayer structure 10 larger than 100 nm may cause a reduction in the crystal quality of the light-emitting layer 14.

### <Light-Emitting Layer (Multiple Quantum Well (MQW) Layer)>

The light-emitting layer 14 is partially provided with V-pits 20. The phrase “light-emitting layer 14 is partially provided with V-pits 20” means that when the upper surface of the light-emitting layer 14 (the surface of the light-emitting layer 14 located on the p-type nitride semiconductor layer 16 side) is observed by AFM, V-pits 20 are observed as black spots on the upper surface of the light-emitting layer 14 (reverse hexagonal pyramid-like holes in the light-emitting layer 14) (see FIG. 3). FIG. 3 shows the results of observation of the upper surface of the light-emitting layer 14 by AFM.

In the light-emitting layer 14, a barrier layer is disposed between well layers, and barrier layers and well layers are alternately stacked. An intermediate layer 15 (described later) is disposed on the well layer located on the most p-type nitride semiconductor layer 16 side among the plurality of the well layers contained in the light-emitting layer 14.

The light-emitting layer 14 may be constituted of successively stacked semiconductor layers, which is composed of one or more layers different from the barrier layers and the well layers, the barrier layers, and the well layers. The length of one cycle of the light-emitting layer 14 (the sum of the thickness of the barrier layer and the thickness of the well layer) is preferably, for example, 5 nm or more and 200 nm or less.

### (Well Layer)

The composition of each well layer is preferably adjusted depending on the light emission wavelength required for the nitride semiconductor light-emitting element 1. For example, the well layer is preferably an Al_{c}Ga_{d}In_{1-c-d}N (0≦c<1, 0<d≦1) layer and more preferably an Al-free InₑGa₁₋ₑN (0<e≦1) layer. In the case of emitting ultraviolet light having a wavelength of 375 nm or less, since the well layer of the light-emitting layer 14 needs to have an increased band gap energy, the composition of each well layer preferably contains Al.

In the light-emitting layer 14, the compositions of the well layers are preferably the same as one another. This can make the light emitted by recombination of electrons and holes in the well layers have the same wavelength. As a result, the emission spectrum width of the nitride semiconductor light-emitting element 1 can be reduced.

It is preferred to reduce the amount of conductive impurities in the well layer located on the p-type nitride semiconductor layer 16 side as much as possible. In other words, the well layer located on the p-type nitride semiconductor layer 16 side is preferably grown without introducing any impurity raw-material gas. This makes it difficult to cause non-emitting recombination in each well layer and thereby can enhance the light emission efficiency of the nitride semiconductor light-emitting element 1. In contrast, the well layer located on the substrate 3 side (the n-type contact layer 8 side) may contain an n-type impurity. This can reduce the driving voltage of the nitride semiconductor light-emitting element 1.

The thicknesses of the well layer are not particularly limited and are preferably the same as one another. If the well layers have the same thickness, since the quantum levels of the well layers are the same, the well layers therefore generate light having the same wavelength by recombination of electrons and holes. This can narrow the emission spectrum width of the nitride semiconductor light-emitting element 1.

In contrast, if the well layers have intentionally different compositions and thicknesses, the emission spectrum width of the nitride semiconductor light-emitting element 1 can be broadened. Accordingly, in the case of using the nitride semiconductor light-emitting element 1 for the purpose, such as lighting, the well layers preferably intentionally have different compositions or thicknesses. For example, the thicknesses of the well layers can be changed within a range of 1 nm or more and 7 nm or less. If the thickness of a well layer is outside this range, the light emission efficiency of the nitride semiconductor light-emitting element 1 may be decreased.

The light-emitting layer 14 may contain any number of the well layers and preferably contains, for example, 2 or more and 20 or less layers, more preferably 3 or more and 15 or less layers, and further preferably 4 or more and 12 or less layers.

### (Barrier Layer)

The thickness of each barrier layer is not particularly limited and is preferably 1 nm or more and 10 nm or less and more preferably 3 nm or more and 7 nm or less. The driving voltage of the nitride semiconductor light-emitting element 1 decreases with the thickness of each barrier layer. However, a significantly small thickness of each barrier layer may cause a reduction in the light emission efficiency of the nitride semiconductor light-emitting element 1.

The concentration of the n-type impurity in the barrier layer is not particularly limited and is preferably appropriately adjusted as necessary. In addition, among the plurality of the barrier layers contained in the light-emitting layer 14, the barrier layer located on the substrate 3 side (n-type contact layer 8 side) preferably contains an n-type impurity, and the barrier layer located on the p-type nitride semiconductor layer 16 side preferably contains the n-type impurity at a concentration lower than that in the barrier layer located on the substrate 3 side or does not intentionally contain the n-type impurity.

### <Intermediate Layer>

The intermediate layer 15 is disposed between the light-emitting layer 14 and the p-type nitride semiconductor layer 16 and has a role of preventing the p-type impurity (e.g., Mg) from diffusing from the p-type nitride semiconductor layer 16 to the light-emitting layer 14 (in particular, well layer). Diffusion of the p-type impurity to the well layer may cause a reduction in the light emission efficiency of the nitride semiconductor light-emitting element 1. Accordingly, an intermediate layer 15 is preferably disposed between the light-emitting layer 14 and the p-type nitride semiconductor layer 16.

The intermediate layer 15 is preferably an Al_{f}Ga_{g}In_{1-f-g}N (0≦f<1, 0<g≦1) layer and more preferably an In-free AlₕGa₁₋ₕN (0<h≦1) layer.

The thickness of the intermediate layer 15 is not particularly limited and is preferably 1 nm or more and 10 nm or less and more preferably 3 nm or more and 5 nm or less. An intermediate layer 15 having a thickness of less than 1 nm may not prevent the p-type impurity from diffusing from the p-type nitride semiconductor layer 16 to the light-emitting layer 14 (in particular, well layer). An intermediate layer 15 having a thickness of larger than 10 nm causes a reduction in efficiency of hole injection into the light-emitting layer 14 and thereby induces a reduction in the light emission efficiency of the nitride semiconductor light-emitting element 1.

### <P-Type Nitride Semiconductor Layer>

FIG. 1 shows that the nitride semiconductor light-emitting element 1 includes a p-type nitride semiconductor layer having a three-layer structure composed of a p-type AlGaN layer 16, a p-type GaN layer 17, and a high-concentration p-type GaN layer 18. The configuration shown in FIG. 1 is, however, a mere example of the configuration of the p-type nitride semiconductor layer. The p-type nitride semiconductor layers 16, 17, and 18 are preferably, for example, Alₛ₄Gaₜ₄Inᵤ₄N (0≦s4≦1, 0≦t4≦1, 0≦u4≦1, s4+t4+u4=1) layers doped with a p-type impurity and more preferably Alₛ₄Ga₁₋ₛ₄N (0<s4≦0.4, preferably 0.1≦s4≦0.3) layers doped with a p-type impurity.

The p-type impurity is not particularly limited and is preferably, for example, magnesium. The carrier concentrations in the p-type nitride semiconductor layers 16, 17, and 18 are each independently preferably 1×10¹⁷/cm³ or more. Since the activity ratio of the p-type impurity is about 0.01, the concentrations of the p-type impurity in the p-type nitride semiconductor layers 16, 17, and 18 (the concentration of the p-type impurity is different the carrier concentration) are preferably 1×10¹⁹/cm³ or more. However, in the p-type nitride semiconductor layers, the concentration of the p-type impurity in the portion located on the light-emitting layer 14 side may be less than 1×10¹⁹/cm³.

The total thickness of the p-type nitride semiconductor layers 16, 17, and 18 is not particularly limited and is preferably 50 nm or more and 300 nm or less. A reduction in the total thickness of the p-type nitride semiconductor layers 16, 17, and 18 can shorten the heating time in the growth period of these layers. This can prevent the p-type impurity from diffusing to the light-emitting layer 14.

### <N-Side Electrode, Transparent Electrode, and P-Side Electrode>

The n-side electrode 21 and the p-side electrode 25 are electrodes for supplying driving voltage to the nitride semiconductor light-emitting element 1. The n-side electrode 21 and the p-side electrode 25 each preferably include a pad electrode part and a branch electrode part connected to the pad electrode part (FIG. 2). This can diffuse current. However, at least one of the n-side electrode 21 and the p-side electrode 25 may be constituted of only a pad electrode part.

An insulating layer for preventing the injection of current into the p-side electrode 25 is preferably disposed below the p-side electrode 25. This reduces the quantity of light shielded by the p-side electrode 25 among the light generated in the light-emitting layer 14.

The n-side electrode 21 is preferably constituted of, for example, a titanium layer, an aluminum layer, and a gold layer stacked in this order. The n-side electrode 21 preferably has a thickness of 1 μm or more under the assumption that the n-side electrode 21 is subjected to wire bonding.

The p-side electrode 25 is preferably constituted of, for example, a nickel layer, an aluminum layer, a titanium layer, and a gold layer stacked in this order, or may be composed of the same materials as those of the n-side electrode 21. The p-side electrode 25 preferably has a thickness of 1 μm or more under the assumption that the p-side electrode 25 is subjected to wire bonding.

The transparent electrode 23 is preferably a transparent conductive film of, for example, indium tin oxide (ITO) or indium zinc oxide (IZO) and preferably has a thickness of 20 nm or more and 200 nm or less.

### <Film Thickness Ratio R of Thickness of N-Type Contact Layer to Thickness of Underlayer>

It has been recently revealed that the ESD defective rate (the defective rate determined based on the results of investigation for the quality of ESD resistance by screening) depends on the film thickness ratio R. FIG. 4 shows the relationship (experimental results) between the film thickness ratio R and the ESD defective rate, when the total of the thickness T₁ of the underlayer 7 and the thickness T₂ of the n-type contact layer 8 is constant. The “ESD defective rate” shown on the vertical axis of FIG. 4 means the rate of the ESD defective rate at each film thickness ratio R to the ESD defective rate at a film thickness ratio R of 1.

If the total of the thickness T₁ of the underlayer 7 and the thickness T₂ of the n-type contact layer 8 is constant, the ESD defective rate increased with the film thickness ratio R (=T₂/T₁). It was demonstrated from FIG. 4 that the ESD defective rate can be suppressed to be low if the film thickness ratio R is 0.8 or less and that the ESD defective rate can be further suppressed to be low if the film thickness ratio R is 0.6 or less. Accordingly, the film thickness ratio R is 0.8 or less and preferably 0.6 or less.

Specifically, the underlayer 7 preferably has a thickness T₁ of 3.3 μm or more and 8 μm or less, and the n-type contact layer 8 preferably has a thickness T₂ of 2 μm or more and 6 μm or less.

More preferably, the underlayer 7 has a thickness T₁ of 3.7 μm or more and 7.5 μm or less, and the n-type contact layer 8 has a thickness T₂ of 2 μm or more and 4.5 μm or less.

The underlayer 7 more preferably has a thickness T₁ of 4.5 μm or more. This improves the crystallinity and improves the light output of the nitride semiconductor light-emitting element 1. In addition, the in-plane density of V-pits 20 is reduced; an increase in the resistance of the n-type contact layer 8 is suppressed; and the operating voltage of the nitride semiconductor light-emitting element 1 is suppressed to be low.

The term “thickness Ti of underlayer 7” refers to the size of the underlayer 7 in the stacking direction of the nitride semiconductor layer. When the underlayer 7 has an uneven thickness, the term “thickness T₁ of underlayer 7” refers to the minimum value in the size of the underlayer 7 in the stacking direction of the nitride semiconductor layer. In the case shown in FIG. 1, the term “thickness Ti of underlayer 7” refers to the distance from the boundary between the underlayer 7 and the n-type contact layer 8 to the boundary between the buffer layer and the underlayer 7 on the convexes 3A of the substrate 3. The thickness Ti of the underlayer 7 can be determined according to, for example, a method of observing the composition of the nitride semiconductor light-emitting element 1 and the impurity distribution by SIMS or a method of observing a cross section of the nitride semiconductor light-emitting element 1 with a scanning capacitance microscope (SCM).

The term “thickness T₂ of n-type contact layer 8” refers to the size of the n-type contact layer 8 in the stacking direction of the nitride semiconductor layer. When the n-type contact layer 8 has an uneven thickness, the term “thickness T₂ of n-type contact layer 8” refers to the maximum value in the size of the n-type contact layer 8 in the stacking direction of the nitride semiconductor layer. In the case shown in FIG. 1, the term “thickness T₂ of n-type contact layer 8” refers to the distance from the boundary between the underlayer 7 and the n-type contact layer 8 to the boundary between the low-temperature n-type nitride semiconductor layer (V-pit generating layer) 9 and the n-type contact layer 8. The thickness T₂ of the n-type contact layer 8 can be determined by the same method as that in the thickness T₁ of the underlayer 7.

### <In-Plane Density of V-Pits>

In the process of making the underlayer 7 to grow on the buffer layer 5 formed on the substrate 3, a large amount of crystal defects occurs. However, a large amount of crystal defects gradually decreases with the progress of growth of the underlayer 7 or by the growth of the n-type contact layer 8.

In the growth process of the low-temperature n-type nitride semiconductor layer (V-pit generating layer) 9, if the dislocation extended from the underlayer 7 crosses the growth face of the low-temperature n-type nitride semiconductor layer (V-pit generating layer) 9, formation of a V-pit 20 starts at the crossing point. Accordingly, the number density of the V-pits 20 on the surface of the light emitting layer 14 located on the p-type nitride semiconductor layer 16 side (hereinafter, written as “in-plane density of V-pits 20”) reflects the in-plane density of dislocations extended from the underlayer 7. However, a dislocation may newly occur in the growth process of the n-type buffer layer 11. In addition, not all of the dislocations extended from the underlayer 7 form V-pits 20. Therefore, the in-plane density of V-pits 20 does not strictly correspond to the in-plane density of dislocations extended from the underlayer 7.

In prevention of a reduction in light emission efficiency of the nitride semiconductor light-emitting element 1 by the dislocations penetrating the light-emitting layer 14, V-pits 20 are indispensable (the reasons therefor will be described later). However, from the viewpoint of that the in-plane density of V-pits 20 reflects the in-plane density of dislocations extended from the underlayer 7, the in-plane density of V-pits 20 is preferably as low as possible and is preferably 1.5×10⁸/cm² or less. For example, the in-plane density of V-pits 20 in the image shown in FIG. 3 is 1.2×10⁸/cm².

Regarding the underlayer 7 and the n-type contact layer 8, it is required to reduce the number of the dislocations extending upward (the light-emitting layer 14 side) as much as possible for enhancing the light emission efficiency of the nitride semiconductor light-emitting element 1 at the actual operating temperature and for enhancing the temperature characteristics of the nitride semiconductor light-emitting element 1. Regarding the n-type buffer layer 11, it is required to prevent occurrence of new dislocations in the n-type buffer layer 11 and to form V-pits 20 as much as possible by the dislocations present in the n-type buffer layer 11. FIG. 5 shows the results of investigation of the relationship between the in-plane density of V-pits 20 and the light output of the nitride semiconductor light-emitting element 1 by variously changing the growth conditions of the nitride semiconductor layer constituting the nitride semiconductor light-emitting element 1 to change the in-plane density of V-pits 20. As understood from FIG. 5, the light output of the nitride semiconductor light-emitting element 1 increased with a decrease in the in-plane density of V-pits 20.

In detail, seven different nitride semiconductor light-emitting elements were produced by variously changing the growth conditions of the nitride semiconductor layers constituting the nitride semiconductor light-emitting elements 1. The resulting nitride semiconductor light-emitting elements were each investigated for the relationship between the film thickness ratio R and the ESD defective rate and the relationship between the in-plane density of V-pits 20 and the light output of the nitride semiconductor light-emitting element 1. The results thereof are shown in FIGS. 4 and 5. The nitride semiconductor light-emitting element giving one of the two results shown in the region X in FIG. 4 was the same nitride semiconductor light-emitting element as that giving one of the two results shown in the region Y in FIG. 5. The nitride semiconductor light-emitting element giving the other of the two results shown in the region X in FIG. 4 was the same nitride semiconductor light-emitting element as that giving the other of the two results shown in the region Y in FIG. 5. It was revealed from the above that if the film thickness ratio R is 0.8 or less and the in-plane density of V-pits 20 is 1.5×10⁸/cm² or less, improvements in the light emission efficiency of the nitride semiconductor light-emitting element 1 at the actual operating temperature and the temperature characteristic of the nitride semiconductor light-emitting element 1 and an improvement in the ESD resistance of the nitride semiconductor light-emitting element 1 can be realized without causing conflict. More preferably, the in-plane density of V-pits 20 is 1.2×10⁸/cm² or less. The in-plane density of V-pit 20 can be determined according to, for example, a method of observing the surface of the light-emitting layer 14 located on the p-type nitride semiconductor layer 16 side by AFM or a method of observing cathode luminescence.

The reasons for that the V-pits 20 are indispensable for preventing a reduction in light emission efficiency of the nitride semiconductor light-emitting element 1 due to dislocations (penetration dislocation) penetrating the light-emitting layer 14 will be described below. Since the occurrence of V-pits 20 is assumed to be caused by penetration dislocations, many of the penetration dislocations are assumed to exist inside the V-pits 20. Here, since the electrons and holes injected into the light-emitting layer 14 can be prevented from reaching the inside of V-pits 20, the electrons and holes injected into the light-emitting layer 14 can be prevented from reaching the penetration dislocations. This can prevent the electrons and holes injected into the light-emitting layer 14 from being captured by the penetration dislocations and thereby can prevent occurrence of non-emitting recombination. Accordingly, the light emission efficiency of the nitride semiconductor light-emitting element 1 can be prevented from reducing. Driving of the nitride semiconductor light-emitting element 1 at a high temperature or by a large current increases the diffusion length of the carrier (electrons or holes). Therefore, the effects described above become significant in driving at a high temperature or driving by a large current.

### <Composition of Underlayer and Composition of N-Type Contact Layer>

Preferably, the underlayer 7 is made of a nitride semiconductor represented by the formula: Alₓ₁In_{y1}Ga_{1-x1-y1}N (0≦x1<1, 0≦y1≦1), and the n-type contact layer 8 is made of a nitride semiconductor represented by the formula: Alₓ₂In_{y2}Ga_{1-x2-y2}N (0≦x2<1, 0≦y2≦1). This can suppress the lattice mismatch between the light-emitting layer 14 and the underlayer 7 and between the light-emitting layer and the n-type contact layer 8 to the minimum, and thereby the crystallinity of the light-emitting layer 14 can be increased. In addition, the nitride semiconductor light-emitting element 1 having excellent environment resistance and capable of be stably used can be provided.

More preferably, the underlayer 7 and the n-type contact layer 8 have the same composition but have different concentrations of a conductive impurity. This can suppress the lattice mismatch between the underlayer 7 and the n-type contact layer 8 to the minimum and thereby can prevent occurrence of crystal defects. As a result, the crystallinity is improved.

The phrase “the underlayer 7 and the n-type contact layer 8 have the same composition” means that the nitride semiconductor constituting the underlayer 7 and the nitride semiconductor constituting the n-type contact layer 8 are the same. Specifically, the kinds of the elements contained in the nitride semiconductor constituting the underlayer 7 are the same as the kinds of the element constituting the n-type contact layer 8. When the nitride semiconductor constituting the underlayer 7 is represented by the formula: Alₓ₁In_{y1}Ga_{1-x1-y1}N (0≦x1<1, 0≦y1≦1) and the nitride semiconductor constituting the n-type contact layer 8 is represented by the formula: Alₓ₂In_{y2}Ga_{1-x2-y2}N (0≦x2<1, 0≦y2≦1), x1 is 0.9 times or more and 1.1 times or less x2, and y1 is 0.9 times or more and 1.1 times or less y2.

For example, both the underlayer 7 and the n-type contact layer 8 are preferably made of GaN. This simplifies the control of the compositions and therefore can stably produce nitride semiconductor light-emitting elements 1 for a long time. If the light-emitting layer 14 emits ultraviolet or near-ultraviolet rays, both the underlayer 7 and the n-type contact layer 8 are preferably made of AlGaN.

The phrase “the underlayer 7 and the n-type contact layer 8 have different concentrations of a conductive impurity” means that the concentration of the conductive impurity in the underlayer 7 is a half or less of the concentration of the conductive impurity in the n-type contact layer 8. Preferably, the concentration of the conductive impurity in the underlayer 7 is one-tenth or less of the concentration of the conductive impurity in the n-type contact layer 8.

### [Method of Producing Nitride Semiconductor Light-Emitting Element]

For example, the nitride semiconductor light-emitting element 1 can be produced according to the method shown below.

First, a buffer layer 5 is formed on a substrate 3 by, for example, sputtering. Next, an underlayer 7, an n-type contact layer 8, a low-temperature n-type nitride semiconductor layer (V-pit generating layer) 9, a multilayer structure 10, a light-emitting layer 14, an intermediate layer 15, and p-type nitride semiconductor layers 16, 17, and 18 are successively formed on the buffer layer 5 by, for example, an MOCVD method.

Next, the p-type nitride semiconductor layers 16, 17, and 18, the intermediate layer 15, the light-emitting layer 14, the multilayer structure 10, the low-temperature n-type nitride semiconductor layer (V-pit generating layer) 9, and the n-type contact layer 8 are etched such that the n-type contact layer 8 is partially exposed. An n-side electrode 21 is formed on the upper surface of the n-type contact layer 8 exposed by the etching.

In addition, a transparent electrode 23 and a p-side electrode 25 are successively stacked on the upper surface of the p-type nitride semiconductor layer 18. Subsequently, a transparent protective film 27 is formed so as to cover the transparent electrode 23 and the side surface of each layer exposed by the etching. This gives the nitride semiconductor light-emitting element 1 shown in FIG. 1. The composition, thickness, and other factors of each layer are the same as those mentioned in the column “Configuration of nitride semiconductor light-emitting element”. Preferred growth conditions of each layer are shown below.

### (Growth of Underlayer)

A substrate 3 provided with a buffer layer 5 is put in a first MOCVD apparatus to grow an underlayer 7 at preferably 800° C. or more and 1250° C. or less, more preferably 900° C. or more and 1150° C. or less. This can form an underlayer 7 having reduced crystal defects and having excellent crystal quality.

Preferably, an underlayer (a part of the underlayer 7) having inclined facets is grown by the facet growth mode, and an underlayer (a part of the underlayer 7) is grown by the embedded growth mode so as to embed the gap between the inclined facets. An underlayer 7 having a flat growth face is thus formed. This can form an underlayer 7 having reduced crystal defects and having excellent crystal quality.

In general, in the facet growth mode, the pressure in the growth period is high and the growth temperature is low, compared to those in the embedded growth mode. For example, a part of the underlayer 7 can be grown at a pressure of 500 Torr and a temperature of 990° C. by the facet growth mode, and the residual part of the underlayer 7 can be grown at a pressure of 200 Torr and a temperature of 1080° C. by the embedded growth mode.

### (Growth of N-Type Contact Layer)

For example, an n-type contact layer 8 is grown on the upper surface of the underlayer 7 by, for example, an MOCVD method at preferably 800° C. or more and 1250° C. or less, more preferably 900° C. or more and 1150° C. or less. This can grow an n-type contact layer 8 having reduced crystal defects and having excellent crystal quality.

### (Growth of Low-Temperature N-Type Nitride Semiconductor Layer (V-Pit Generating Layer))

A low-temperature n-type nitride semiconductor layer (V-pit generating layer) 9 is preferably grown at a temperature lower than the growth temperature of the n-type contact layer 8. Specifically, the growth temperature of the low-temperature n-type nitride semiconductor layer (V-pit generating layer) is preferably 950° C. or less and more preferably 700° C. or more, further preferably 750° C. or more. A growth temperature of the low-temperature n-type nitride semiconductor layer (V-pit generating layer) of 700° C. or more can maintain a high light emission efficiency in the light-emitting layer 14.

### (Growth of Multilayer Structure)

A multilayer structure 10 is preferably grown at a temperature not higher than the growth temperature of the low-temperature n-type nitride semiconductor layer (V-pit generating layer) 9. Since this makes the V-pits 20 large, most of the dislocations penetrating the light-emitting layer 14 exist inside the V-pits 20, resulting in an improvement in the light emission efficiency of the nitride semiconductor light-emitting element 1. In order to effectively obtain this effect, the growth temperature of the multilayer structure 10 is preferably 600° C. or more and more preferably 700° C. or more.

The low-temperature n-type nitride semiconductor layer (V-pit generating layer) 9 and the multilayer structure 10 may be grown at the same growth temperature. This can prevent occurrence of new crystal results due to variation in temperature.

### (In-Plane Density of V-Pits and Growth Conditions of Nitride Semiconductor Layer)

In order to reduce the in-plane density of V-pits 20, the followings are important. For example, an aluminum nitride-based material is used as the material of the buffer layer 5, and in the initial period of the growth of the underlayer 7 (the step of filling the unevenness of the surface of the substrate 3 with the underlayer 7), the underlayer 7 is facet grown in the concaves 3B while the underlayer 7 being prevented from growing to the convexes 3A. As a result, dislocations are concentrated at the centers of the convexes 3A. This can reduce dislocations extending from the underlayer 7 to the n-type contact layer 8 to thereby reduce the in-plane density of V-pits 20. It is also necessary to optimize the conditions for growing the n-type contact layer 8 not to increase dislocations in the n-type contact layer 8. Furthermore, the in-plane density of V-pits 20 can be controlled to 1.5×10⁸/cm² or less by maintaining each of the growth rates of the low-temperature n-type nitride semiconductor layer 9 and the multilayer structure 10 to about 0.5 nm/min or more and about 50 nm/more less and adjusting each of the impurity concentrations to 1×10¹⁷/cm³ or more and 1×10¹⁹/cm³ or less. More preferably, each of the growth rates of the low-temperature n-type nitride semiconductor layer 9 and the multilayer structure 10 is maintained to 1.0 nm/min or more and 15 nm/min or less, and each of the impurity concentrations is adjusted to 1×10¹⁸/cm³ or more and 1×10¹⁹/cm³ or less.

In the crystal growth of each layer by an MOCVD method, raw-material gases shown below can be used. As the raw-material gas of Ga, for example, trimethylgallium (TMG) or triethylgallium (TEG) can be used. As the raw-material of Al, for example, trimethylaluminium (TMA) or triethylaluminium (TEA) can be used. As the raw-material of In, for example, trimethylindium (TMI) or triethylindium (TEI) can be used. As the raw-material of N, for example, NH₃ or dimethylhydrazine (DMHy) can be used. As the raw-material of Si serving as an n-type impurity, for example, SiH₄, Si₂H₆, or organic Si can be used. As the raw-material of Mg serving as a p-type impurity, for example, Cp₂Mg can be used.

### [Summarization of Embodiments]

The nitride semiconductor light-emitting element 1 shown in FIG. 1 at least comprises an underlayer 7, an n-type contact layer 8, a light-emitting layer 14, and p-type nitride semiconductor layers 16, 17, and 18 successively disposed on a substrate 3. The film thickness ratio R, which is the ratio of the thickness of the n-type contact layer 8 to the thickness of the underlayer 7, is 0.8 or less. The number density of V-pits in the surface of the light emitting layer 14 located on the p-type nitride semiconductor layers 16, 17, and 18 side is 1.5×10⁸/cm² or less. This can realize improvements in the light emission efficiency at the actual operating temperature and the temperature characteristic and an improvement in the ESD resistance without causing conflict.

The film thickness ratio R is preferably 0.6 or less. This further improves the ESD resistance of the nitride semiconductor light-emitting element 1.

The concentration of the conductive impurity in the underlayer 7 is preferably 1.0×10¹⁷/cm³ or less. This reduces the dislocation density and improves the crystallinity. More preferably, the underlayer 7 is intentionally undoped with any conductive impurity. This can maintain good crystallinity of the light-emitting layer 14.

The underlayer 7 is preferably made of a nitride semiconductor represented by the formula: Alₓ₁In_{y1}Ga_{1-x1-y1}N (0≦x1<1, 0≦y1≦1). The n-type contact layer is preferably made of a nitride semiconductor represented by the formula: Alₓ₂In_{y2}Ga_{1-x2-y2}N (0≦x2<1, 0≦y2≦1). This can suppress the lattice mismatch between the light-emitting layer 14 and the underlayer 7 and between the light-emitting layer 14 and the n-type contact layer 8 to the minimum, and thereby the crystallinity of the light-emitting layer 14 can be increased.

More preferably, the underlayer 7 and the n-type contact layer 8 differ in the concentration of the conductive impurity, but have the same composition. This suppresses the lattice mismatch between the underlayer 7 and the n-type contact layer 8 to the minimum, and thereby the crystallinity is improved.

Both the underlayer 7 and the n-type contact layer 8 are preferably made of GaN. This simplifies the control of the compositions and therefore can stably produce nitride semiconductor light-emitting elements 1 for a long time.

Both the underlayer 7 and the n-type contact layer 8 are preferably made of AlGaN. This can provide a nitride semiconductor light-emitting element 1 that emits ultraviolet or near-ultraviolet rays.

The underlayer 7 preferably has a thickness of 4.5 μm or more. This reduces the in-plane density of V-pits 20, suppresses the increase in resistance of the n-type contact layer 8, and suppresses the operating voltage of the nitride semiconductor light-emitting element 1 to be low.

### EXAMPLES

The present invention will now be described in more detail with reference to examples, but is not limited to the following examples.

### Example 1

### Production of Nitride Semiconductor Light-Emitting Element

First, a sapphire substrate (diameter: 150 mm) having an upper surface provided with an uneven shape composed of convexes and concaves was prepared. The convexes had the same cross-sectional shape as that of the convexes 3A shown in FIG. 1 and therefore had a conical tip having a low height. The convexes were disposed at positions corresponding to the vertices of approximate triangles in a planar view, and the intervals between adjacent vertices were each 2 μm. The shape of the convexes on the upper surface of the sapphire substrate was of an approximate circle having a diameter of about 1.2 μm. The convexes had a height of about 0.6 μm. The concaves had the same cross-sectional shape as that of the concaves 3B shown in FIG. 1.

The upper surface of the sapphire substrate provided with convexes and concaves was subjected RCA washing. The sapphire substrate after the RCA washing was set in a chamber and heated. A buffer layer (thickness: 25 nm) of AIN crystals was formed on the upper surface of the substrate by reactive sputtering using an Al target under a nitrogen-containing argon atmosphere.

The sapphire substrate provided with the buffer layer was put in an MOCVD apparatus, and the temperature of the sapphire substrate was raised to 1000° C. An underlayer of undoped GaN was grown on the upper surface of the buffer layer by an MOCVD method, and an n-type contact layer of Si-doped GaN was then grown on the upper surface of the underlayer. The thickness T₁ (see FIG. 1) of the underlayer was 6 μm, and the thickness T₂ (see FIG. 1) of the n-type contact layer was 3 μm. The film thickness ratio R was, therefore, 0.5. The n-type contact layer had an n-type dopant concentration of 1×10¹⁹/cm³.

The temperature of the sapphire substrate was reduced to 801° C., and a low-temperature n-type nitride semiconductor layer (V-pit generating layer) (thickness: 30 nm) of Si-doped GaN was then grown on the upper surface of the n-type contact layer. The low-temperature n-type nitride semiconductor layer (V-pit generating layer) had an n-type impurity concentration of 9×10¹⁸/cm³.

In a state of maintaining the temperature of the sapphire substrate at 801° C., a multilayer structure was grown. Specifically, 20 sets of a wide band gap layer (thickness: 1.55 nm) made of Si-doped GaN and a narrow band gap layer (thickness: 1.55 nm) made of Si-doped InGaN alternately stacked were grown. The concentration of the n-type impurity in each layer constituting the multilayer structure 10 was 7×10¹⁸/cm³. The narrow band gap layers each had a composition of In_{y}Ga_{1-y}N (y=0.04).

The temperature of the sapphire substrate was reduced to 672° C., and a light-emitting layer was then grown. Specifically, eight well layers were formed by alternately growing barrier layers (thickness: 4.0 nm) made of GaN and well layers (thickness: 3.7 nm) made of InGaN. The two barrier layers located on the multilayer structure side had an n-type impurity concentration of 4.3×10¹⁸/cm³, and other barrier layers were undoped layers.

The well layer was an undoped InₓGa₁₋ₓN layer (x=0.20) grown using nitrogen gas as the carrier gas. The composition x of In in the well layers was set (x=0.20) by adjusting the flow rate of TMI such that the light emitted by the well layers by photoluminescence was 448 nm.

An intermediate layer (thickness: 4 nm) made of undoped GaN was grown on the upper surface of the light-emitting layer (specifically, the upper surface of the uppermost well layer).

The temperature of the sapphire substrate was raised to 1000° C., and a p-type Al_{0.18}Ga_{0.82}N layer, a p-type GaN layer, and a p-type contact layer were then successively grown on the upper surface of the intermediate layer.

The p-type contact layer, the p-type GaN layer, the p-type Al_{0.18}Ga_{0.82}N layer, the intermediate layer, the light-emitting layer, the multilayer structure, the low-temperature n-type nitride semiconductor layer (V-pit generating layer), and the n-type contact layer were etched to expose a part of the n-type contact layer. An n-side electrode 21 made of, for example, Au was formed on the upper surface of the n-type contact layer exposed by the etching. In addition, a transparent electrode made of ITO and a p-side electrode made of, for example, Au were successively formed on the upper surface of the p-type contact layer. A transparent protective film made of SiO₂ was formed so as to cover the transparent electrode and the side surface of each layer exposed by the etching.

The sapphire substrate was divided into chips having a size of 620×680 μm. The nitride semiconductor light-emitting elements of the present invention were thus formed.

### <Evaluation>

The resulting nitride semiconductor light-emitting element was subjected to screening (by applying a stress of about 2 KV by a human body model) for investigating the quality of ESD resistance. As a result, the ESD defective rate was 5% or less to show very excellent ESD resistance.

The resulting nitride semiconductor light-emitting element was mounted on a TO-18 stem, and the light output of the nitride semiconductor light-emitting element was measured without sealing with a resin. When the nitride semiconductor light-emitting element was driven at 120 mA in an environment of 25° C., the light output P(25) was 181.5 mW (dominant wavelength: 450 nm) at a driving voltage of 3.05 V. In addition, when the nitride semiconductor light-emitting element was driven at 120 mA in an environment of 80° C., the light output P(80) was 176.8 mW at a driving voltage of 3.05 V. This demonstrates that the nitride semiconductor light-emitting element of this Example had a temperature characteristic (P(80)/P(25)) of 97.4%. In examples, the light output P measured in an environment of 25° C. is noted as “P(25)”, and the light output P measured in an environment of 80° C. is noted as “P(80)”.

A light-emitting layer was grown according to the above-described method with a sapphire substrate of a batch different from that of the sapphire substrate for producing the nitride semiconductor light-emitting elements. Immediately after the growth of the light-emitting layer, the temperature of the sapphire substrate was decreased, and the substrate was taken out from the MOCVD apparatus. Immediately after this, the in-plane density of V-pits was determined with an AFM apparatus. The in-plane density of V-pits was 1.0×10⁸/cm².

### Comparative Example 1

A nitride semiconductor light-emitting element was produced in accordance with the method of Example 1 except that the thickness T₁ (see FIG. 1) of the underlayer was 4.5 μm and the thickness T₂ (see FIG. 1) of the n-type contact layer was 4.5 μm. In this Comparative Example, the film thickness ratio R was 1.0.

The nitride semiconductor light-emitting element of this Comparative Example was evaluated in accordance with the method of Example 1. The ESD defective rate increased to about 10%. When the nitride semiconductor light-emitting element was driven at 120 mA in an environment of 25° C., the light output P(25) was 178 mW at a driving voltage of 3.05 V.

### Example 2

### Production of Nitride Semiconductor Light-Emitting Element

A nitride semiconductor light-emitting element was produced in accordance with the method of Example 1 except that the configuration of the multilayer structure was different. Specifically, five sets of a wide band gap layer (thickness: 11 nm) made of Si-doped GaN and a narrow band gap layer (thickness: 11 nm) made of Si-doped InGaN alternately stacked were grown. All of the layers constituting the multilayer structure 10 had an n-type impurity concentration of 6×10¹⁸cm/³. All of the narrow band gap layers had a composition of In_{y}Ga_{1-y}N (y=0.04).

### <Evaluation>

The ESD defective rate was investigated in accordance with the method of Example 1. The ESD defective rate was 5% or less to show very excellent ESD resistance.

The P(25) and the P(80) were measured in accordance with the method of Example 1. The P(25) was 180 mW (dominant wavelength: 450 nm), and the P(80) was 174.6 mW. This demonstrates that the nitride semiconductor light-emitting element of this Example had a temperature characteristic (P(80)/P(25)) of 97.0%.

The in-plane density of V-pits was determined in accordance with the method of Example 1. The in-plane density of V-pits was 1.05×10⁸/cm².

### Comparative Example 2

A nitride semiconductor light-emitting element was produced in accordance with the method of Example 2 except that the thickness T₁ (see FIG. 1) of the underlayer was 4.5 μm and the thickness T₂ (see FIG. 1) of the n-type contact layer was 4.5 μm. In this Comparative Example, the film thickness ratio R was 1.0.

The nitride semiconductor light-emitting element of this Comparative Example was evaluated in accordance with the method of Example 1. The ESD defective rate increased to about 10%. When the nitride semiconductor light-emitting element was driven at 120 mA in an environment of 25° C., the light output P(25) was 176 mW at a driving voltage of 3.05 V.

### Example 3

A nitride semiconductor light-emitting element was produced in accordance with the method of Example 1 excepting the following points: An underlayer and an n-type contact layer were grown with a first MOCVD apparatus, and the sapphire substrate was then taken out from the first MOCVD apparatus and was put in a second MOCVD apparatus. Subsequently, in the second MOCVD apparatus, a low-temperature n-type nitride semiconductor layer (V-pit generating layer), a multilayer structure, a light-emitting layer, an intermediate layer, a p-type Al_{0.18}Ga_{0.82}N layer, a p-type GaN layer, and a p-type contact layer were successively grown. The thus-produced nitride semiconductor light-emitting element was evaluated in accordance with the method of Example 1. It was demonstrated that the nitride semiconductor light-emitting elements of Example 1 and this Example had no difference in the characteristics.

In this Example, the apparatus for growing the underlayer and the n-type contact layer having large thicknesses (a high-rate growth is needed) and the apparatus for growing the light-emitting layer (a low-rate growth and a growth with highly uniform crystal quality are needed) can be changed. The film-forming apparatus can be thus selected so as to be optimum for growing the individual layer. Accordingly, the manufacturing efficiency of the nitride semiconductor light-emitting element is improved.

### Example 4

### Production of Nitride Semiconductor Light-Emitting Element

A nitride semiconductor light-emitting element was produced in accordance with the method of Example 1 except that the thickness T₁ (see FIG. 1) of the underlayer was 7 μm and the thickness T₂ (see FIG. 1) of the n-type contact layer was 2 μm. In this Example, the film thickness ratio R was 0.29.

### <Evaluation>

The ESD defective rate was investigated in accordance with the method of Example 1. The ESD defective rate was 3% or less to show more excellent ESD resistance than those in Examples 1 to 3.

The P(25) and the P(80) were measured in accordance with the method of Example 1. The P(25) was 182.5 mW (dominant wavelength: 450 nm), and the P(80) was 178.3 mW. This demonstrates that the nitride semiconductor light-emitting element of this Example had a temperature characteristic (P(80)/P(25)) of 97.7%.

The in-plane density of V-pits was determined in accordance with the method of Example 1. The in-plane density of V-pits was 0.8×10⁸/cm².

It should be understood that the embodiments and the examples disclosed herein are illustrative in all aspects and are not intended to be limiting. The scope of the present invention should be defined by claims for patent rather than the above-mentioned description, and it is intended that all modifications in the meaning and range equivalent to the scope of claims for patent are included.

### REFERENCE SIGNS LIST

1 nitride semiconductor light-emitting element
3 substrate
3A convex
3B concave
5 buffer layer
7 underlayer
8 n-type contact layer
9 low-temperature n-type nitride semiconductor layer
10 multilayer structure
11 n-type buffer layer
14 light-emitting layer
15 intermediate layer
16, 17, 18 p-type nitride semiconductor layer
20 pit
21 n-side electrode
23 transparent electrode
25 p-side electrode
27 transparent protective film
30 mesa portion

1. A nitride semiconductor light-emitting element at least comprising an underlayer, an n-type contact layer, a light-emitting layer, and a p-type nitride semiconductor layer successively disposed on a substrate, wherein
a ratio of a light emission efficiency at 80° C. of environmental temperature to the light emission efficiency at 25° C. of environmental temperature is 97% or more;
a film thickness ratio R being a ratio of the thickness of the n-type contact layer to the thickness of the underlayer is 0.8 or less; and
the surface of the light-emitting layer located on the p-type nitride semiconductor layer side has a number density of V-pits of less than 1.0×10⁸/cm².

2. The nitride semiconductor light-emitting element according to claim 1, wherein the film thickness ratio R is 0.6 or less.

3. The nitride semiconductor light-emitting element according to claim 1, wherein the underlayer has a conductive impurity concentration of 1.0×10¹⁷/cm³ or less.

4. The nitride semiconductor light-emitting element according to claim 3, wherein the underlayer is intentionally undoped with any conductive impurity.

5. The nitride semiconductor light-emitting element according to claim 1, wherein
the underlayer is made of a nitride semiconductor represented by a formula: Alₓ₁In_{y1}Ga_{1-x1-y1}N (0≦x1<1, 0≦y1≦1); and
the n-type contact layer is made of a nitride semiconductor represented by a formula: Alₓ₂In_{y2}Ga_{1-x2-y2}N (0≦x2<1, 0≦y2≦1).

6. The nitride semiconductor light-emitting element according to claim 5, wherein the underlayer and the n-type contact layer have different conductive impurity concentrations and have the same composition.

7. The nitride semiconductor light-emitting element according to claim 5, wherein both the underlayer and the n-type contact layer are made of GaN.

8. The nitride semiconductor light-emitting element according to claim 5, wherein both the underlayer and the n-type contact layer are made of AlGaN.

9. The nitride semiconductor light-emitting element according to claim 1, wherein the underlayer has a thickness of 4.5 μm or more.
